(19) United States
(12) Patent Application Publication
(10) Pub. No.: US 2026/0255600 A1
(43) Pub. Date: Aug. 27, 2026

(54) SEMICONDUCTOR DEVICE AND METHOD OF MANUFACTURING SEMICONDUCTOR DEVICE

(71) Applicant: Kioxia Corporation, Tokyo (JP)

(72) Inventor: Noritaka ISHIHARA, Nagoya Aichi (JP)

(73) Assignee: Kioxia Corporation, Tokyo (JP)

(21) Appl. No.: 19/235,718

(22) Filed: Jun. 12, 2025

(30) Foreign Application Priority Data
Feb. 26, 2025 (JP) 2025-028973

(51) Int. Cl. H10B 43/27; H10B 43/35; H10D 30/01; H10D 30/69; H10D 62/40; H10D 62/60; H10D 62/834; H10D 64/68; H10P 14/20

(52) U.S. Cl. CPC H10B 43/27; H10B 43/35; H10D 30/0413; H10D 30/693; H10D 62/405; H10D 62/60; H10D 62/834; H10D 64/683; H10P 14/3802

(57) ABSTRACT

According to one embodiment, a semiconductor device includes a stacked body in which a plurality of conductive layers and a plurality of insulating layers are alternately stacked one by one, and a pillar extending in the stacked body in a stacking direction of the stacked body, in which the pillar includes a first semiconductor layer extending in the stacked body in the stacking direction, and a second semiconductor layer protruding from a side wall of the first semiconductor layer toward a first insulating layer at least at a height position of the first insulating layer positioned near a center of the stacked body in the stacking direction among the plurality of insulating layers.

### CROSS-REFERENCE TO RELATED APPLICATIONS

This application is based upon and claims the benefit of priority from Japanese Patent Application No. 2025-028973, filed on February 26, 2025; the entire contents of which are incorporated herein by reference.

### FIELD

Embodiments described herein relate generally to a semiconductor device and a method of manufacturing a semiconductor device.

### BACKGROUND

In a three-dimensional nonvolatile memory, a plurality of memory cells including a channel layer are arranged in a height direction of a pillar extending in the height direction on a side surface of the pillar. Here, the channel layer is crystallized to improve memory cell characteristics, but variation in the memory cell characteristics may occur due to incomplete crystallization.

### BRIEF DESCRIPTION OF THE DRAWINGS

FIGS. 1A and 1B are diagrams illustrating a schematic configuration example of a semiconductor device according to an embodiment;

FIGS. 2A to 2D are cross-sectional views illustrating an example of a configuration of the semiconductor device according to the embodiment;

FIGS. 3A to 3C are diagrams sequentially illustrating a part of a procedure of a method of manufacturing the semiconductor device according to the embodiment;

FIGS. 4A and 4B are diagrams sequentially illustrating a part of the procedure of the method of manufacturing the semiconductor device according to the embodiment;

FIGS. 5A and 5B are diagrams sequentially illustrating a part of the procedure of the method of manufacturing the semiconductor device according to the embodiment;

FIGS. 6A and 6B are diagrams sequentially illustrating a part of the procedure of the method of manufacturing the semiconductor device according to the embodiment;

FIGS. 7A and 7B are diagrams sequentially illustrating a part of the procedure of the method of manufacturing the semiconductor device according to the embodiment;

FIGS. 8A to 8F are diagrams sequentially illustrating a part of the procedure of the method of manufacturing the semiconductor device according to the embodiment;

FIGS. 9A to 9F are diagrams sequentially illustrating a part of the procedure of the method of manufacturing the semiconductor device according to the embodiment;

FIGS. 10A and 10B are diagrams sequentially illustrating a part of the procedure of the method of manufacturing the semiconductor device according to the embodiment;

FIGS. 11A and 11B are diagrams sequentially illustrating a part of the procedure of the method of manufacturing the semiconductor device according to the embodiment;

FIGS. 12A and 12B are diagrams sequentially illustrating a part of the procedure of the method of manufacturing the semiconductor device according to the embodiment;

FIGS. 13A and 13B are diagrams sequentially illustrating a part of the procedure of the method of manufacturing the semiconductor device according to the embodiment; and

FIGS. 14A to 14F are diagrams sequentially illustrating a part of a procedure of a method of manufacturing a semiconductor device according to a modification example of the embodiment.

### DETAILED DESCRIPTION

In general, according to one embodiment, a semiconductor device includes a stacked body in which a plurality of conductive layers and a plurality of insulating layers are alternately stacked one by one, and a pillar extending in the stacked body in a stacking direction of the stacked body, in which the pillar includes a first semiconductor layer extending in the stacked body in the stacking direction, and a second semiconductor layer protruding from a side wall of the first semiconductor layer toward a first insulating layer at least at a height position of the first insulating layer positioned near a center of the stacked body in the stacking direction among the plurality of insulating layers.

Hereinafter, an embodiment of the present invention will be described in detail with reference to the drawings. The present invention is not limited to the following embodiment. Components in the following embodiment include components that can be easily conceived by those skilled in the art and components that are substantially the same.

### Embodiment

Hereinafter, the embodiment will be described in detail with reference to the drawings.

### Configuration Example of Semiconductor Device

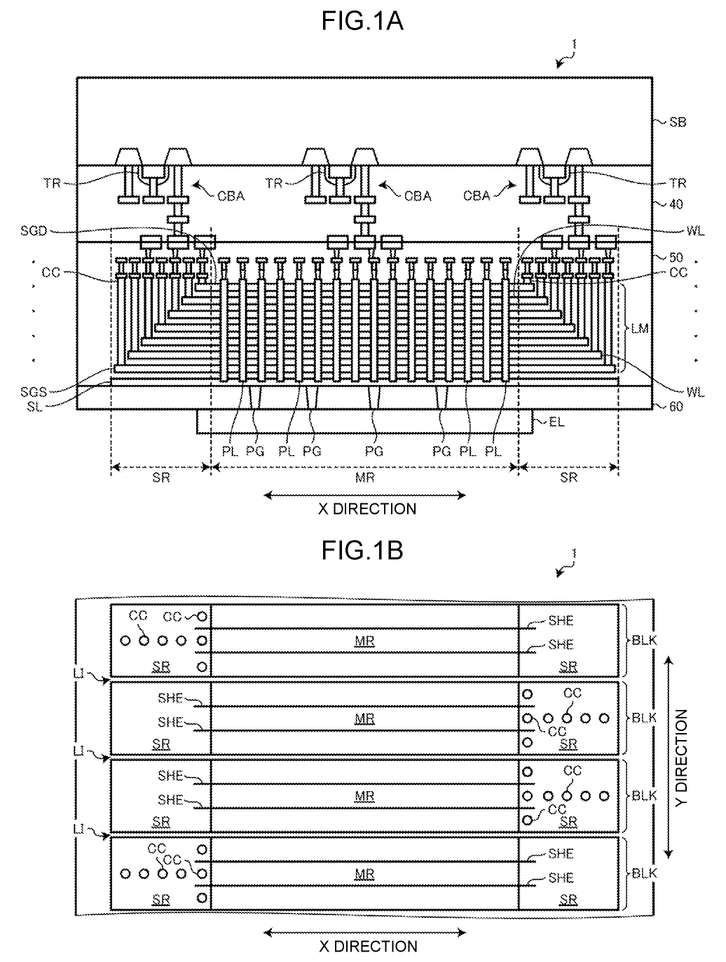

FIGS. 1A and 1B are diagrams illustrating a schematic configuration example of a semiconductor device 1 according to the embodiment. More specifically, FIG. 1A is a cross-sectional view of the semiconductor device 1 taken in an X direction, and FIG. 1B is a schematic plan view illustrating a layout of the semiconductor device 1.

Note that hatching is omitted in FIG. 1A to facilitate understanding of the drawings. In FIG. 1A, configurations that are not necessarily provided in the same cross-section are illustrated together, and a part of upper wirings or the like are not illustrated.

In the present specification, both of the X direction and a Y direction are directions along a surface of a word line WL, and the X direction and the Y direction are orthogonal to each other. An electrical drawing direction of the word line WL may be referred to as a first direction, and the first direction is a direction along the X direction. A direction intersecting with the first direction may be referred to as a second direction, and the second direction is a direction along the Y direction. Note that the semiconductor device 1 may include manufacturing errors, and thus the first direction and the second direction are not necessarily orthogonal to each other.

As illustrated in FIG. 1A, the semiconductor device 1 includes a semiconductor substrate SB in which an electrode film EL, a source line SL, one or more selection gate lines SGS, a plurality of word lines WL, one or more selection gate lines SGD, and a peripheral circuit CBA are sequentially provided from a lower side of the drawing.

The source line SL is disposed on the electrode film EL with an insulating layer 60 interposed therebetween. A plurality of plugs PG are disposed in the insulating layer 60, and electrical connection between the source line SL and the electrode film EL is maintained via the plugs PG. Although not illustrated in the drawings, an electrode pad for supplying power and signals from outside to the semiconductor device 1 is provided on the same layer as the electrode film EL. The selection gate line SGS, the plurality of word lines WL, and the selection gate line SGD are sequentially stacked on the source line SL.

As illustrated in FIGS. 1A and 1B, a memory region MR is disposed in a center portion of the plurality of word lines WL and the like in the X direction, and a staircase region SR is disposed in each of both end portions of the plurality of word lines WL and the like in the X direction. The memory region MR and the staircase regions SR are divided into a plurality of regions by a plurality of plate-like contacts LI penetrating the plurality of word lines WL and the like and extending in a direction along the X direction.

A region disposed between the plate-like contacts LI adjacent to each other in the Y direction and including the memory region MR and the staircase regions SR will be referred to as a block region BLK. As described below, the memory region MR includes a plurality of memory cells that store data in a nonvolatile manner, and the above-described block region BLK is an erasing unit of data.

A plurality of separation layers SHE penetrating the selection gate line SGD and extending in a direction along the X direction are disposed between the plate-like contacts LI adjacent to each other in the Y direction. The plurality of separation layers SHE extend in a direction along the X direction across the entire memory region MR, and reach a part of the staircase regions SR in both end portions in the X direction.

In the memory region MR, a plurality of pillars PL penetrating the word lines WL and the selection gate lines SGD and SGS in a stacking direction thereof are disposed. A lower end of the pillar PL reaches the source line SL. The plurality of memory cells are formed in intersection portions between the pillars PL and the word lines WL. As a result, the semiconductor device 1 is configured as a three-dimensional nonvolatile memory in which memory cells are three-dimensionally disposed in the memory region MR.

In the staircase region SR, the plurality of word lines WL and the selection gate lines SGD and SGS are processed in a staircase shape and terminated. Here, as a distance from the memory region MR in the X direction increases, the plurality of word line WL and the selection gate lines SGD and SGS configuring a terrace portion move from an upper layer side to a lower layer side, and thus a height position of the terrace portion decreases to the source line SL side.

In the present specification, a direction in which a terrace surface of the plurality of word lines WL and the selection gate lines SGD and SGS is oriented is defined as an upper side of the semiconductor device 1.

The above-described separation layer SHE extends from the memory region MR to a portion in which the selection gate line SGD of the staircase region SR is processed in a staircase shape. As a result, the selection gate line SGD in one block region BLK is separated into a plurality of regions. In other words, the separation layer SHE penetrates an upper layer portion of the plurality of word lines WL so that the upper layer portion is divided to be a pattern of the plurality of selection gate lines SGD.

In the terrace portions of the steps configured with the plurality of word lines WL and the selection gate lines SGD and SGS, contacts CC each connected to each layer of the word lines WL and the selection gate lines SGD and SGS are disposed. In the word lines WL and the selection gate line SGS, one contact CC is connected to one layer. In the selection gate line SGD, one contact CC is connected to each section separated by the separation layer SHE for each layer.

Here, in one block region BLK, a plurality of contacts CC are disposed in one side of the staircase region SR in the X direction. When seen on one side in the X direction, for example, a plurality of contacts CC are disposed for every two block regions BLK.

That is, in the example of FIG. 1B, in the block region BLK of an uppermost portion of the drawing, a plurality of contacts CC are disposed, for example, in the staircase region SR on a left side of the drawing among the staircase regions SR in both end portions in the X direction. In the block regions BLK below the above-described block region BLK by one layer and by two layers, a plurality of contacts CC are disposed in the staircase region SR on a right side of the drawing among the staircase regions SR in both end portions in the X direction. In the block region BLK of a lowermost portion of the drawing, a plurality of contacts CC are disposed again in the staircase region SR on the left side of the drawing.

Accordingly, in FIG. 1A, the contacts CC in the staircase regions SR in both end portions in the X direction belong to different block regions BLK, and are not actually positioned on the same cross-section.

Due to the contacts CC, the word lines WL and the like stacked in multiple layers are individually drawn. More specifically, a write voltage, a read voltage, and the like are applied from the contacts CC to the memory cells in the memory region MR in the center portion of the plurality of word lines WL via the word line WL at the same height position of each memory cell.

The plurality of word lines WL, the selection gate lines SGD and SGS, the pillars PL, and the contacts CC are covered with an insulating layer 50. The insulating layer 50 is also spread to the periphery of the configuration including the plurality of word lines WL and the like.

The semiconductor substrate SB above the insulating layer 50 that covers the above-described configuration is, for example, a silicon substrate. The peripheral circuit CBA including transistors TR, wirings, and the like is disposed on a surface of the semiconductor substrate SB. Various voltages applied from the contacts CC to the memory cells are controlled by the peripheral circuit CBA electrically connected to the contacts CC. As a result, the peripheral circuit CBA controls an electrical operation of the memory cells.

Since the peripheral circuit CBA is covered with an insulating layer 40 and the insulating layer 40 is bonded to the insulating layer 50 that covers the plurality of word lines WL and the like, the semiconductor device 1 including the configuration of the plurality of word lines WL, the selection gate lines SGD and SGS, the pillars PL, the contacts CC, and the like and the peripheral circuit CBA is configured.

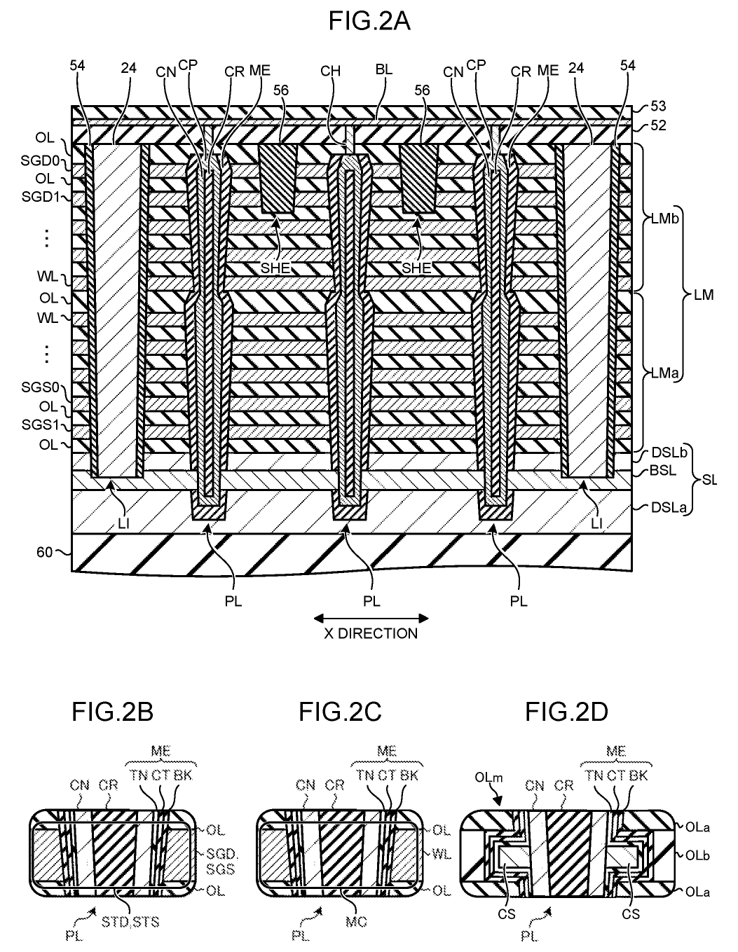

Next, a detailed configuration example of the semiconductor device 1 will be described using FIGS. 2A to 2D. FIGS. 2A to 2D are cross-sectional views illustrating an example of the configuration of the semiconductor device 1 according to the embodiment.

More specifically, FIG. 2A is a cross-sectional view of the memory region MR of the semiconductor device 1 taken in the Y direction. FIG. 2A does not illustrate structures below the insulating layer 60 and structures above an insulating layer 53 described below.

FIG. 2B is an enlarged cross-sectional view illustrating the pillar PL at a height position of the selection gate lines SGD and SGS. FIG. 2C is an enlarged cross-sectional view illustrating the pillar PL at a height position of the word line WL. FIG. 2D is an enlarged cross-sectional view illustrating the pillar PL at a height position of an insulating layer OLm.

As illustrated in FIG. 2A, the source line SL has a multilayer structure in which, for example, a lower source line DSLa, an intermediate source line BSL, and an upper source line DSLb are sequentially stacked on the insulating layer 60. The lower source line DSLa, the intermediate source line BSL, and the upper source line DSLb are, for example, polysilicon layers. Among the source lines, at least the intermediate source line BSL may be a conductive polysilicon layer in which impurity is diffused.

The source line SL is connected to the peripheral circuit CBA via the electrode film EL by a through contact (not illustrated) extending from the electrode film EL to the peripheral circuit CBA in the above-described insulating layer 50 outside a stacked body LM.

The stacked body LM is disposed on the source line SL. The stacked body LM includes stacked bodies LMa and LMb in which a plurality of word lines WL and a plurality of insulating layers OL are alternately stacked one by one.

The stacked body LMa is disposed above the source line SL. On a layer under the lowermost word line WL of the stacked body LMa, a plurality of selection gate lines SGS0 and SGS1 are sequentially disposed from an upper layer side of the stacked body LMa with the insulating layers OL interposed therebetween. The stacked body LMb is disposed on the stacked body LMa. On a layer above the uppermost word line WL of the stacked body LMb, a plurality of selection gate lines SGD0 and SGD1 are sequentially disposed from an upper layer side of the stacked body LMb with the insulating layers OL interposed therebetween.

Note that the numbers of the word line WL and the selection gate lines SGD and SGS stacked in the stacked body LM are freely selected. The word line WL and the selection gate lines SGD and SGS are, for example, tungsten layers or molybdenum layers. The insulating layer OL is, for example, a silicon oxide layer.

As illustrated in FIG. 2D, the stacked body LM includes one or more insulating layers OLm. The insulating layer OLm is a layer in which an insulating layer OLb having different layer properties from those of an insulating layer OLa such as a silicon oxide layer is interposed between insulating layers OLa and OLa.

More specifically, the insulating layer OLb is, for example, a silicon oxycarbide (SiOC) layer, a silicon-germanium (SiGe) layer, or a silicon oxide (SiOx) layer having a lower density than the insulating layer OLa. As a result, the insulating layer OLb has lower resistance to dry etching, wet etching, or the like than the insulating layer OLa.

The entire insulating layer OLm has, for example, a thickness equal to or thicker than thicknesses of other insulating layers OL and is two times or less of the thicknesses of the other insulating layers OL. The insulating layer OLb has a thickness 50% or more and 80% or less of the thickness of the insulating layer OLm and, for example, has a thickness of 20 nm or more and 50 nm or less.

The insulating layer OLm is interposed between the word lines WL in a vertical direction and provided near at least a center of the stacked body LM in the stacking direction instead of the above-described insulating layer OL. Note that the stacked body LM may include a plurality of insulating layers OLm, and here, it is preferable that the plurality of insulating layers OLm are scattered at a predetermined interval in the stacking direction of the stacked body LM.

As illustrated in FIG. 2A, an upper surface of the stacked body LM is sequentially covered with insulating layers 52 and 53. Each of the insulating layers 52 and 53 configures a part of the insulating layer 50 of FIG. 1A.

As described above, the stacked body LM is divided in the Y direction by the plurality of plate-like contacts LI. That is, the plate-like contacts LI are arranged in the Y direction and extend in a direction along the stacking direction of the stacked body LM and the X direction.

Accordingly, the plate-like contact LI continuously extends in the stacked body LM from one end portion to the other end portion of the stacked body LM in the X direction. The plate-like contact LI penetrates the stacked body LM and the upper source line DSLb and reaches the intermediate source line BSL in the memory region MR.

The plate-like contact LI has, for example, a tapered shape in which a width in the Y direction decreases from an upper end portion toward a lower end portion. Alternatively, the plate-like contact LI may have a bowing shape in which the width in the Y direction is maximum at a predetermined position between the upper end portion and the lower end portion.

Each of the plate-like contacts LI includes an insulating layer 54 and a conductive layer 24. The insulating layer 54 is, for example, a silicon oxide layer. The conductive layer 24 is, for example, a tungsten layer or a conductive polysilicon layer.

The insulating layer 54 covers a side wall of the plate-like contact LI facing the Y direction. The conductive layer 24 is filled inside of the insulating layer 54 covering the side wall of the plate-like contact LI, and is electrically connected to the source line SL including the intermediate source line BSL.

Note that, instead of the plate-like contact LI, a plate-like member filled with an insulating layer may penetrate the stacked body LM and extend in a direction along the X direction, thereby dividing the stacked body LM in the Y direction.

The plurality of separation layers SHE penetrating the upper layer portion of the stacked body LMb and extending in a direction along the X direction are disposed between the plate-like contacts LI adjacent to each other in the Y direction. The separation layers SHE are insulating layers 56 such as silicon oxide layers penetrating the selection gate lines SGD0 and SGD1 and reaching the insulating layer OL immediately below the selection gate line SGD1.

In other words, the separation layers SHE penetrating the upper layer portion of the stacked body LMb extend in the X direction in a part of the memory region MR and the staircase region SR between the plate-like contacts LI so that the upper layer portion of the stacked body LMb is divided into the above-described selection gate lines SGD0 and SGD1.

In the memory region MR, a plurality of pillars PL penetrating the stacked body LM, the upper source line DSLb, and the intermediate source line BSL and reaching the lower source line DSLa are spread and disposed.

The plurality of pillars PL are disposed, for example, in a staggered arrangement when seen from the stacking direction of the stacked body LM. Each of the pillars PL has, for example, a circular shape, an elliptical shape, or an oval shape as a cross-sectional shape in a direction along a layer direction of the stacked body LM, that is, along an XY plane.

Each of a part of the pillar PL penetrating the stacked body LMa and a part of the pillar PL penetrating the stacked body LMb has a tapered shape in which a diameter and a cross-sectional area decreases from the upper layer side to the lower layer side. Alternatively, each of a part of the pillar PL penetrating the stacked body LMa and a part of the pillar PL penetrating the stacked body LMb may have, for example, a bowing shape in which the diameter and the cross-sectional area are maximum at a predetermined position between the upper layer side and the lower layer side.

Each of the plurality of pillars PL includes a memory layer ME extending in the stacked body LM in the stacking direction, a channel layer CN provided inside of the memory layer ME and extending in the stacked body LM in the stacking direction, a cap layer CP covering an upper surface of the channel layer CN, and a core layer CR as a core of the pillar PL.

The channel layer CN is in direct contact with the intermediate source line BSL at a depth position of the intermediate source line BSL. That is, the memory layer ME is disposed on a side surface of the pillar PL other than the depth position of the intermediate source line BSL. The memory layer ME is also disposed on a bottom surface of the pillar PL reaching a depth of the lower source line DSLa.

As a result, the channel layer CN is in contact with the intermediate source line BSL on the side surface and electrically connected to the entire source line SL via the intermediate source line BSL.

The cap layer CP is disposed in an upper end portion of the pillar PL, covers at least an upper end portion of the channel layer CN, and is connected to the channel layer CN. The cap layer CP is connected to a bit line BL disposed in the insulating layer 53 via a plug CH disposed in the insulating layers OL and 52 of the uppermost layer of the stacked body LM. The bit line BL extends above the stacked body LM in a direction along the Y direction and intersects with a drawing direction of the word line WL.

As illustrated in FIGS. 2B and 2C, the memory layer ME has a stacked structure including a block insulating layer BK, a charge storage layer CT, and a tunnel insulating layer TN sequentially from an outer peripheral side of the pillar PL. The block insulating layer BK and the tunnel insulating layer TN of the memory layer ME, and the core layer CR are, for example, silicon oxide layers. The charge storage layer CT is, for example, a silicon nitride layer.

The channel layer CN is a semiconductor layer having high crystallinity such as a single crystal silicon layer. Note that a part of the channel layer CN may include polycrystalline silicon. Even then, it is preferable that the channel layer CN includes single crystal silicon as a major component. The channel layer CN may include an additive of at least any of nitrogen, boron, and carbon.

The cap layer CP is, for example, a single crystal semiconductor layer or a polycrystalline semiconductor layer such as a polysilicon layer. When the cap layer CP is a single crystal semiconductor layer, a part of the cap layer CP may include a polycrystalline semiconductor layer. When the cap layer CP is a polycrystalline semiconductor layer, a part of the cap layer CP may include an amorphous semiconductor such as amorphous silicon.

As illustrated in FIG. 2C, with the above-described configuration, the memory cell MC is formed in portions of the side surface of the pillar PL facing each of the word lines WL. By applying a predetermined voltage from the word line WL, data is written into and read from the memory cell MC.

As illustrated in FIG. 2B, a selection gate STD is formed in each of portions of the side surface of the pillar PL facing the selection gate lines SGD0 and SGD1. A selection gate STS is formed in each of portions of the side surface of the pillar PL facing the selection gate lines SGS0 and SGS1 below the word line WL.

By applying a predetermined voltage from the selection gate lines SGD and SGS, the selection gates STD and STS can be switched on or off so that the memory cell MC of the pillar PL belonging to the switched selection gates STD and STS enters a selected state or a non-selected state.

As illustrated in FIG. 2D, a semiconductor layer CS protrudes from a side surface of the channel layer CN into the insulating layer OLb at a height position of the insulating layer OLm. That is, on the side surface of the channel layer CN, one or a plurality of semiconductor layers CS are provided corresponding to the number and positions of the insulating layers OLm in the stacked body LM.

The memory layer ME covers the side surface of the channel layer CN as described above, and continuously covers upper and lower surfaces of the semiconductor layer CS protruding in the insulating layer OLb and a surface thereof facing the insulating layer OLb. As a result, although a thickness of the semiconductor layer CS protruding in the insulating layer OLb varies depending on the thickness of the memory layer ME, the thickness of the semiconductor layer CS protruding in the insulating layer OLb is 15% or more and 25% or less of the thickness of the insulating layer OLb and, for example, is 5 nm or more and 9 nm or less.

The semiconductor layer CS is a semiconductor layer having lower crystallinity than the channel layer CN and is, for example, a polycrystalline silicon layer. Note that a part of the semiconductor layer CS may include single crystal or amorphous silicon. Even then, the semiconductor layer CS includes polycrystalline silicon as a major component. The semiconductor layer CS has, for example, a crystal orientation different from that of the channel layer CN including a single crystal semiconductor as a major component.

### Method of Manufacturing Semiconductor Device

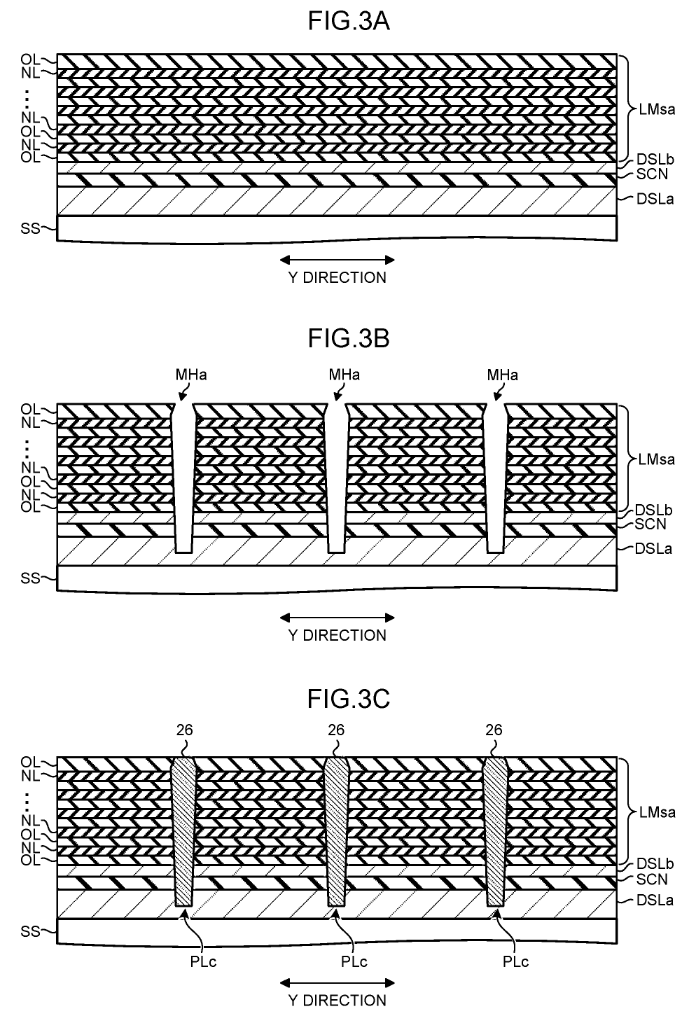

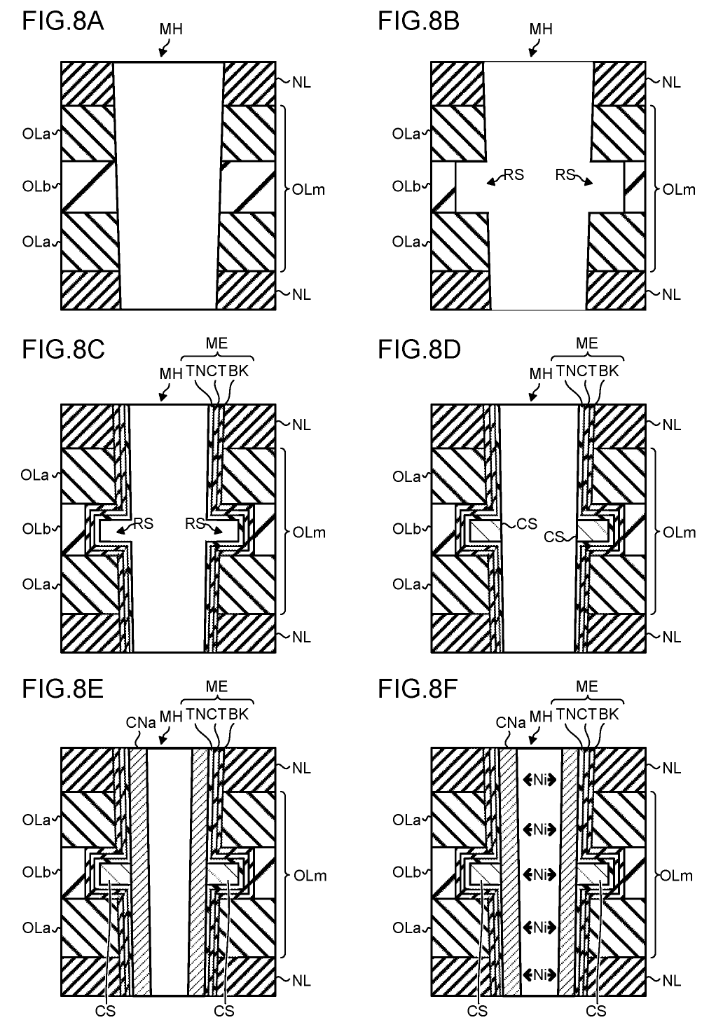

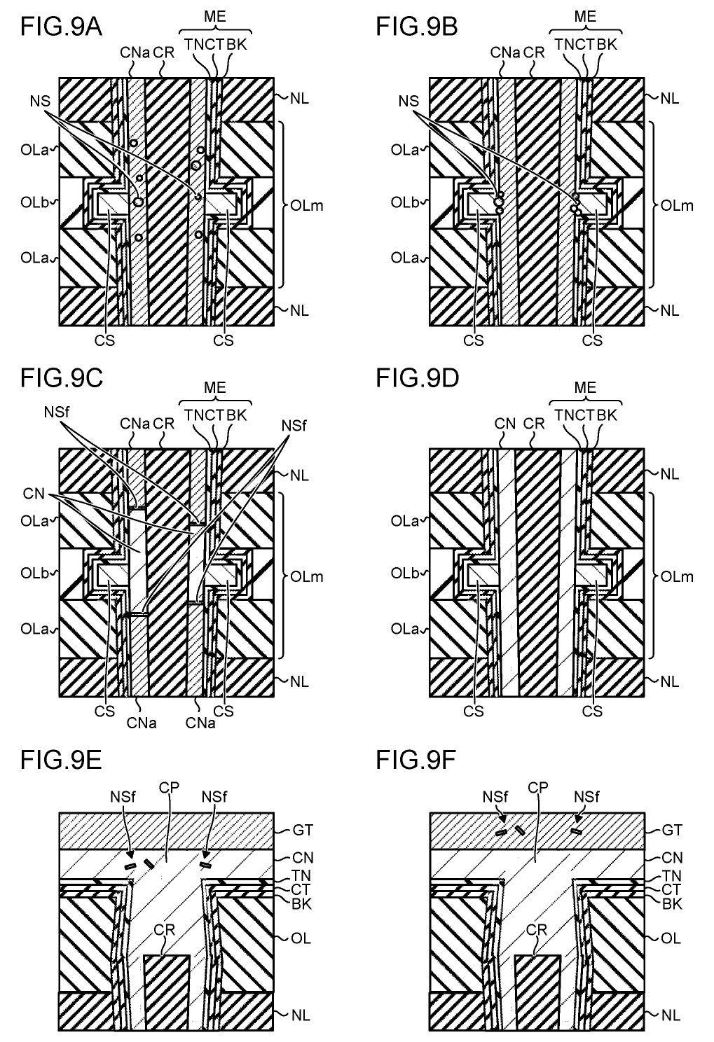

Next, a method of manufacturing the semiconductor device 1 according to the embodiment will be described using FIGS. 3A to 13B. FIGS. 3A to 13B are diagrams sequentially illustrating a part of a procedure of the method of manufacturing the semiconductor device 1 according to the embodiment. FIGS. 3A to 13B except for FIGS. 8A to 9F illustrate cross-sections of a region to become the memory region MR taken in the Y direction. FIGS. 8A to 9F are partially enlarged cross-sectional views at the height position of the insulating layer OLm of the pillar PL during manufacturing.

As illustrated in FIG. 3A, the lower source line DSLa, an intermediate sacrificial layer SCN, and the upper source line DSLb are sequentially formed on a supporting substrate SS.

As the supporting substrate SS, a semiconductor substrate such as a silicon substrate, an insulating substrate such as a ceramic substrate, a conductive substrate, or the like can be used. The above-described insulating layer 60 (refer to FIG. 2A and the like) may be formed on an upper surface side of the supporting substrate SS. The intermediate sacrificial layer SCN is, for example, a silicon nitride layer, and is a layer to be replaced with a polysilicon layer or the like to become the intermediate source line BSL.

A stacked body LMsa in which a plurality of insulating layers NL and the plurality of insulating layers OL are alternately stacked one by one is formed on the upper source line DSLb. The insulating layer NL is, for example, a silicon nitride layer, and functions as a sacrificial layer to be replaced with a conductive material to become the word line WL or the selection gate line SGS.

Next, although not illustrated in the drawing, in a partial region of the stacked body LMsa, the insulating layer NL and the insulating layer OL are processed in a staircase shape. The processing can be performed by repeating slimming of a mask pattern such as a photoresist layer and etching of the insulating layer NL and the insulating layer OL of the stacked body LMsa multiple times.

That is, the mask pattern is formed on an upper surface of the stacked body LMsa, and the insulating layer NL and the insulating layer OL in the exposed portion are removed one by one by etching. In a treatment using oxygen plasma or the like, an end portion of the mask pattern is retracted so that the upper surface of the stacked body LMsa is newly exposed, and the insulating layer NL and the insulating layer OL are further removed one by one by etching. By repeating the treatment multiple times, the stacked body LMsa having a staircase shape is formed in both end portions in the X direction.

Next, the staircase shapes in both end portions in the X direction are covered with a part of the above-described insulating layer 50 (refer to FIG. 1A).

As illustrated in FIG. 3B, a plurality of memory holes MHa extending in the stacked body LMsa in the stacking direction are formed. The plurality of memory holes MHa penetrate the stacked body LMsa, the upper source line DSLb, and the intermediate sacrificial layer SCN and reach the lower source line DSLa. The memory holes MHa are portions to become lower structures of the pillars PL.

As illustrated in FIG. 3C, the memory holes MHa are filled with sacrificial layers 26 such as amorphous silicon layers or CVD-carbon layers. As a result, pillars PLc filled with the sacrificial layers 26 are formed in the plurality of memory holes MHa.

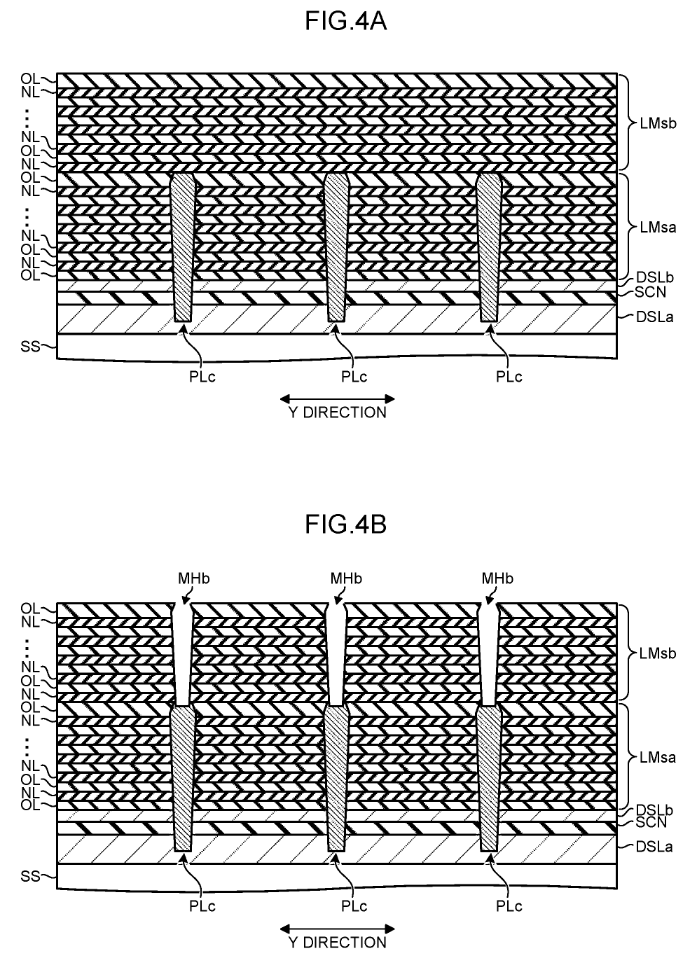

As illustrated in FIG. 4A, a stacked body LMsb in which the plurality of insulating layers NL and the plurality of insulating layers OL are alternately stacked one by one is formed to cover the stacked body LMsa. The insulating layer NL of the stacked body LMsb functions as a sacrificial layer to be replaced with a conductive layer to become the word line WL or the selection gate line SGD.

At least during the above-described formation of the stacked body LMsa illustrated in FIG. 3A or during formation of the stacked body LMsb illustrated in FIG. 4A, one or more insulating layers OLm (refer to FIG. 2D) are interposed between the insulating layers NL instead of the insulating layer OL.

Here, the insulating layer OLa can be formed using a chemical vapor deposition (CVD) method or the like under same conditions as those of the other insulating layers OL.

For example, when a silicon oxycarbide layer is formed as the insulating layer OLb, the insulating layer OLb can be interposed in the insulating layer OLa by adding carbon during formation. For example, when a silicon-germanium layer is formed as the insulating layer OLb, the insulating layer OLb can be interposed in the insulating layer OLa by forming a film using silicon and germanium as materials during formation. For example, when a silicon oxide layer having a low density is formed as the insulating layer OLb, the insulating layer OLb can be interposed in the insulating layer OLa by changing film forming conditions and increasing layer density during formation.

Next, although not illustrated in the drawing, in a partial region of the stacked body LMsb, the insulating layer NL and the insulating layer OL are processed in a staircase shape. As in the above-described treatment on the stacked body LMsa, the processing can be performed by repeating slimming of a mask pattern such as a photoresist layer and etching of the insulating layer NL and the insulating layer OL of the stacked body LMsb multiple times.

Here, by bringing the uppermost step of the staircase portion formed in the stacked body LMsa close to the lowermost step of the staircase portion formed in the stacked body LMsb, a staircase shape is formed continuously from the lower layer side of the stacked body LMsa to the upper layer side of the stacked body LMsb. As a result, the stacked bodies LMsa and LMsb in which staircase regions SR having a staircase shape from the stacked body LMsa to the stacked body LMsb in both end portions in the X direction are formed.

Next, the staircase shape in both end portions in the X direction are further covered with a part of the above-described insulating layer 50 (refer to FIG. 1A).

As illustrated in FIG. 4B, a plurality of memory holes MHb penetrating the stacked body LMsb and connected to each of the plurality of pillars PLc formed in the stacked body LMsa are formed. The memory holes MHb are portions to become upper structures of the pillars PL.

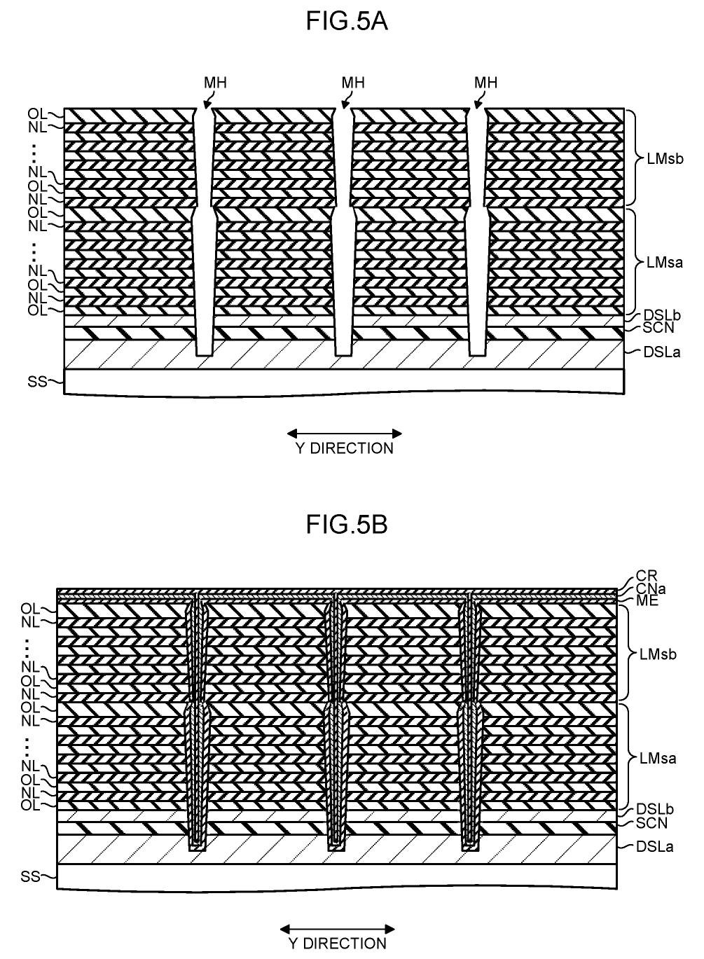

As illustrate in FIG. 5A, the sacrificial layer 26 is removed from the pillar PLc in a bottom of the memory hole MHb. As a result, the memory holes MHa are formed in the bottom of each of the plurality of memory holes MHb, and a plurality of memory holes MH penetrating the stacked bodies LMsb and LMsa, the upper source line DSLb, and the intermediate sacrificial layer SCN and reaching the lower source line DSLa are formed.

When the sacrificial layer 26 filled in the pillar PLc is a CVD-carbon layer or the like, by removing the mask pattern used during the above-described formation of the memory holes MHb in FIG. 4B by ashing using oxygen plasma or the like, the sacrificial layers 26 can be collectively removed from the pillars PLc.

As illustrated in FIG. 5B, the memory layer ME including the block insulating layer BK, the charge storage layer CT, and the tunnel insulating layer TN (refer to FIGS. 2B and 2C) sequentially from the side wall side of the memory hole MH is formed on a side wall of the memory holes MH and a bottom surface thereof in which the lower source line DSLa is exposed. The memory layer ME is also formed on an upper surface of the stacked body LMsb.

A channel layer CNa and the core layer CR are formed sequentially in the memory hole MH. As a result, the channel layer CN is formed on the memory layer ME covering the side surface and the bottom surface of the memory hole MH, and a core layer CRa is filled in a center portion of the memory hole MH. The channel layer CNa and the core layer CR are also formed sequentially on the upper surface of the stacked body LMsb with the memory layer ME interposed therebetween.

The channel layer CNa is a semiconductor layer to become the channel layer CN. Here, the entire channel layer CNa is, for example, an amorphous semiconductor layer such as an amorphous silicon layer. In the above description, an additive of at least any of nitrogen, boron, or carbon may be added to the channel layer CNa.

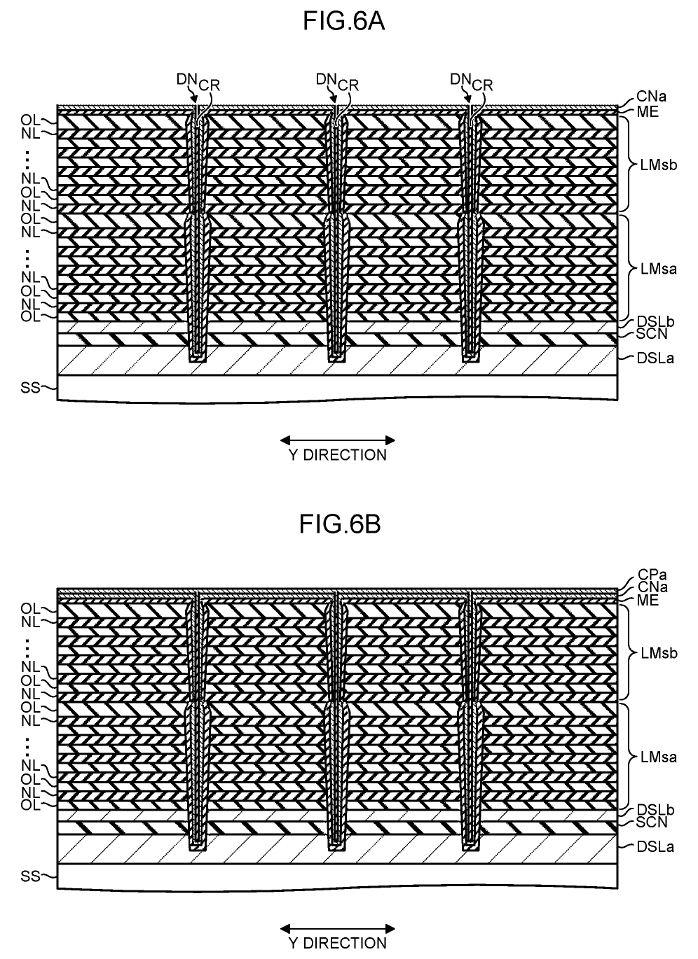

As illustrated in FIG. 6A, the core layer CR formed on the upper surface of the stacked body LMsb is etched back and removed, and the core layer CR in the memory hole MH is retracted to form a depression DN in an upper end portion of the memory hole MH.

As illustrated in FIG. 6B, a cap layer CPa is formed in the above-described depression DN. Here, as in the channel layer CNa, the cap layer CPa is, for example, an amorphous semiconductor layer such as an amorphous silicon layer. The cap layer CPa is also formed on the upper surface of the stacked body LMsb with the memory layer ME and the channel layer CNa interposed therebetween.

Next, the channel layer CNa and the cap layer CPa are crystallized and, for example, the single crystal channel layer CN and the single crystal cap layer CP are formed.

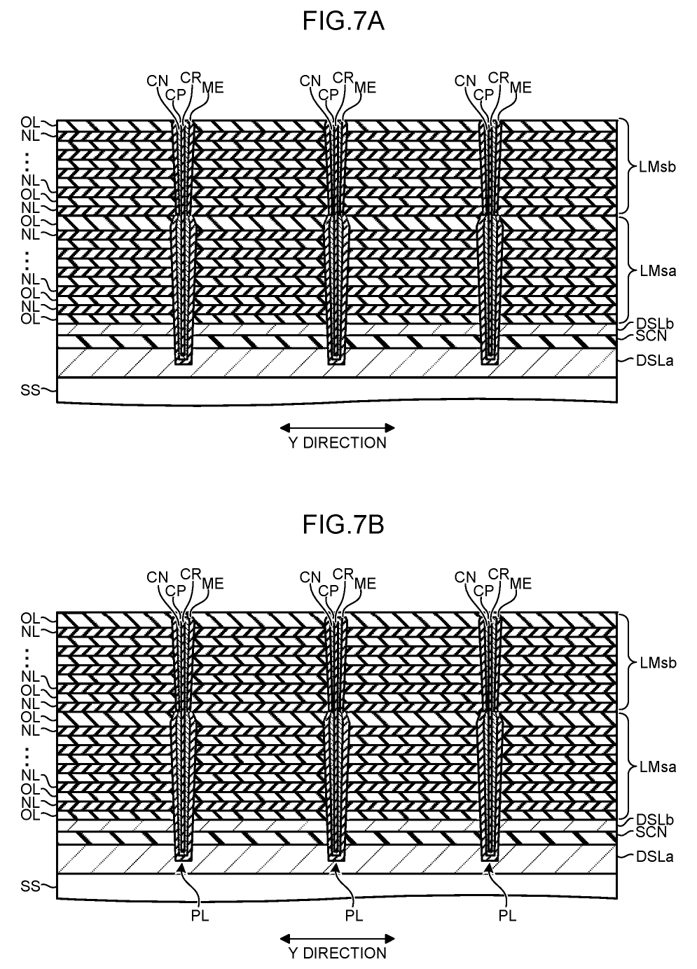

As illustrated in FIG. 7A, the cap layer CP, the channel layer CN, and the memory layer ME of the upper surface of the stacked body LMsb are removed by CMP or the like together with a part of the insulating layer OL that is the uppermost layer of the stacked body LMsb.

As illustrated in FIG. 7B, the insulating layer OL that is the uppermost layer of the stacked body LMsb and is thinned by CMP or the like is stacked. As a result, the pillar PL in which the cap layer CP is embedded in the uppermost insulating layer OL is formed. Note that, here, the memory layer ME covers an entire side wall of the pillar PL, and a part of the side surface of the channel layer CN is not exposed from the memory layer ME.

When the memory layer ME, the channel layer CNa, and the core layer CR are formed in the memory hole MH, formation of the semiconductor layer CS protruding from a side wall of the channel layer CNa is performed in parallel. As described above, crystallization of the channel layer CNa and the cap layer CPa is performed after formation of the cap layer CPa.

Hereinafter, FIGS. 8A to 9F illustrate a detailed example of a formation method of the memory layer ME, the channel layer CNa, and the core layer CR including formation of the semiconductor layer CS, a crystallization method of the channel layer CNa, and the like.

FIG. 8A illustrates a state in which the memory hole MH penetrating the stacked bodies LMsa and LMsb including the insulating layer OLm is formed. As described above, the insulating layer OLm has a configuration in which the insulating layer OLb is inserted into the insulating layer OLa, and the thickness of the insulating layer OLb is, for example, 50% or more and 80% or less of the entire thickness of the insulating layer OLm.

As illustrated in FIG. 8B, inside of the memory hole MH is treated by dry etching, wet etching, or the like. Here, etching isotropically progresses in wet etching, and when dry etching is used, a plasma source is selected or etching conditions are adjusted to perform isotropic etching.

As described above, the insulating layer OLb is a layer having lower etching resistance than the insulating layers OL and OLa, and thus, by the above-described treatment, the insulating layer OLb in the insulating layer OLm is retracted from the side wall of the memory hole MH to the periphery by a substantially equal distance, and a recess portion RS interposed between an end surface of the retracted insulating layer OLb and the insulating layer OLa in the vertical direction of the insulating layer OLb is formed on the side wall of the memory hole MH.

As illustrated in FIG. 8C, the memory layer ME covering the side wall of the memory hole MH and sequentially including the block insulating layer BK, the charge storage layer CT, and the tunnel insulating layer TN is formed. Here, the memory layer ME continuously covers the side wall of the memory hole MH, the upper and lower surfaces of the above-described recess portion RS, and the end surface of the insulating layer OLb.

As illustrated in FIG. 8D, a polysilicon layer or the like is filled in the recess portion RS to form the semiconductor layer CS. More specifically, by forming the polysilicon layer or the like covering the entire side wall of the memory hole MH including the portion of the recess portion RS and removing the polysilicon layer from the side wall of the memory hole MH, the semiconductor layer CS filled in the recess portion RS can be formed. Here, the semiconductor layer CS is a polycrystalline semiconductor layer such as a polysilicon layer as described above. Note that a part of the semiconductor layer CS may include, for example, an amorphous semiconductor such as an amorphous silicon layer.

Since the size of the recess portion RS is reduced by the memory layer ME formed in the recess portion RS, the thickness of the semiconductor layer CS is, for example, 15% or more and 25% or less of the thickness of the insulating layer OLb.

As illustrated in FIG. 8E, the channel layer CNa covering the entire side wall of the memory hole MH is formed. Here, the channel layer CNa is, for example, an amorphous semiconductor layer such as an amorphous silicon layer as described above.

As illustrated in FIG. 8F, a metal element such as nickel is introduced into the channel layer CNa. Introduction of the metal element into the channel layer CNa can be performed, for example, by forming a metal layer on the channel layer CNa by chemical vapor deposition (CVD) or electroplating.

As illustrated in FIG. 9A, the metal element such as nickel introduced into the channel layer CNa is randomly diffused in the channel layer CNa. Here, a part of the metal element may be silicided to form a silicide NS such as nickel silicide.

A void in the memory hole MH as such is filled with a silicon oxide layer or the like to form the core layer CR.

Next, as illustrated in FIGS. 6A and 6B described above, the core layer CR formed on the upper surface of the stacked body LMsb is etched back and removed, and the core layer CR in the memory hole MH is retracted to form the depression DN in the upper end portion of the memory hole MH. The cap layer CPa such as an amorphous silicon layer is formed in the depression DN.

As illustrated in FIG. 9B, the supporting substrate SS is heated to a predetermined temperature and the entire supporting substrate SS is annealed. Here, the temperature of the annealing treatment is, for example, a low temperature in which crystallization of the channel layer CNa does not occur.

Meanwhile, at an interface between the semiconductor layer CS such as a polysilicon layer and the channel layer CNa such as an amorphous silicon layer, activation energy required for forming the silicide NS decreases, and the silicide NS is likely to be formed. When the channel layer CNa includes an additive such as nitrogen, boron, or carbon, the silicide NS is likely to be formed due to such additives.

Accordingly, aggregation of the silicide NS occurs at the interface between the semiconductor layer CS and the channel layer CNa. The silicide NS promotes crystallization of the channel layer CNa. That is, the silicide NS functions as a catalyst for crystallization of the channel layer CNa.

As illustrated in FIG. 9C, due to the aggregation of the silicide NS, for example, from the interface between the semiconductor layer CS and the channel layer CNa as an origin, crystallization of the channel layer CNa such as an amorphous silicon layer progresses in the vertical direction of the stacked bodies LMsa and LMsb.

Here, a part of the silicide NS functioning as the catalyst for crystallization of the channel layer CNa is finely cut into metal fragments NSf, and the metal fragments NSf are diffused in the channel layer CNa. The channel layer CNa of a part to which the metal fragment NSf entered changes into the above-described channel layer CN such as a single crystal silicon layer.

As such, a process of crystallizing the channel layer CNa by low-temperature annealing treatment in which the silicide NS or the like is used as the catalyst will also be referred to as a metal-assisted annealing treatment.

Such crystallization does not progress in the semiconductor layer CS that is originally the polysilicon layer or the like. Therefore, the semiconductor layer CS that is originally the polysilicon layer or the like and the channel layer CN in which crystallization is progressed by the metal-assisted annealing treatment have different crystal orientations.

As illustrated in FIG. 9D, crystallization of the channel layer CNa progresses so that the entire channel layer CNa becomes, for example, the single crystal channel layer CN, and then the metal-assisted annealing treatment ends. Here, when the cap layer CPa is formed as an amorphous semiconductor layer, the cap layer CPa may also be crystallized to form the single crystal cap layer CP.

Note that the channel layer CN and the cap layer CP may include a polycrystalline semiconductor or the like due to partially incomplete crystallization or the like.

When the plurality of insulating layers OLm are formed in the stacked bodies LMsa and LMsb, a grain boundary may be formed in the channel layer CN at a height position between the insulating layers OLm. That is, since crystallization of the channel layer CNa progresses in the vertical direction from the height position of each of the insulating layers OLm as an origin, the single crystal channel layer CN or the like extending from the height position of the insulating layer OLm on the upper layer side and the single crystal channel layer CN or the like extending from the height position of the insulating layer OLm on the lower layer side are bonded, and a grain boundary may be formed at an interface therebetween.

As described above, even when a part of the channel layer CN includes a grain boundary or a polycrystalline semiconductor, the channel layer CN including a single crystal semiconductor as a major component is formed by the metal-assisted annealing treatment in which the interface between the semiconductor layer CS and the channel layer CNa functions as an origin.

As described above, by disposing the semiconductor layer CS as an origin of crystallization of the channel layer CNa at any position in the stacked body LM, an origin position of crystallization and a grain boundary position in the channel layer CNa can be controlled.

As illustrated in FIG. 9E, the metal fragment NSf is segregated in the channel layer CN. A gettering layer GT such as an amorphous silicon layer is formed on an upper surface of the channel layer CN.

As illustrated in FIG. 9F, by performing the annealing treatment, the metal fragment NSf that was segregated in the channel layer CN moves into the gettering layer GT. As a result, most of the metal fragments NSf in the channel layer CN can be removed.

Next, the gettering layer GT is removed.

As described above, the channel layer CN as a single crystal semiconductor layer or the like is formed.

In the metal-assisted annealing treatment, as the thickness of the layer to be crystallized increases, crystallization is more likely to be promoted. Accordingly, the above-described channel layer CNa may be formed to be thicker than the channel layer CN to be finally included in the pillar PL and then crystallized.

When the channel layer CNa is formed thick, after crystallizing the channel layer CNa, the cap layer CP and the core layer CR can be temporarily removed, and the channel layer CN exposed in the memory hole MH can be slimmed so that the layer thickness is adjusted to a desired value. Next, the core layer CR is formed again in the memory hole MH, and the cap layer CP is formed in an upper end portion of the core layer CR or the like. The cap layer CP formed as described above is, for example, a polycrystalline semiconductor layer such as a polysilicon layer. Here, a part of the cap layer CP may include an amorphous semiconductor such as amorphous silicon.

Accordingly, even when a part of the cap layer CP includes amorphous silicon or the like or when a part of the semiconductor layer CS formed as a polysilicon layer or the like includes an amorphous silicon layer or the like, the cap layer CP and the semiconductor layer CS are subjected to various thermal histories by various subsequent treatments in manufacturing steps of the semiconductor device 1. Therefore, proportions of amorphous portions in the cap layer CP and the semiconductor layer CS may be further reduced or the amorphous portions may be eliminated in the semiconductor device 1 as a final product.

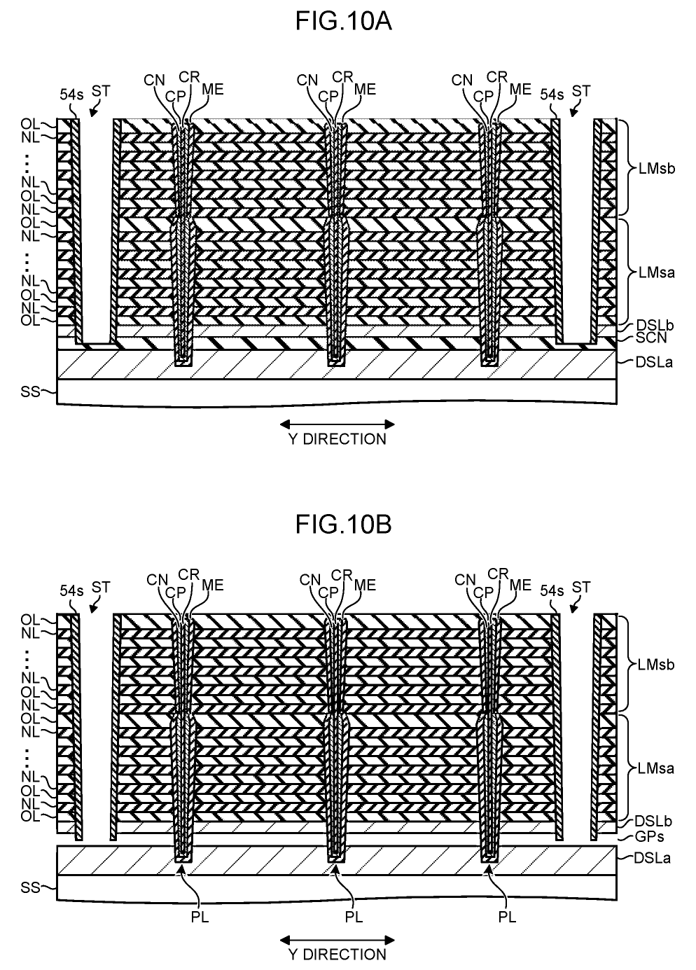

As illustrated in FIG. 10A, a slit ST penetrating the stacked bodies LMsb and LMsa in which the pillar PL is formed and the upper source line DSLb and reaching the intermediate sacrificial layer SCN is formed. An insulating layer 54s is formed on a side wall of the slit ST facing the Y direction. The slit ST also extends in the stacked bodies LMsa and LMsb in a direction along the X direction.

As illustrated in FIG. 10B, for example, by flowing a liquid such as hot phosphoric acid for removing the intermediate sacrificial layer SCN via the slit ST of which the side wall is protected with the insulating layer 54s, the intermediate sacrificial layer SCN interposed between the lower source line DSLa and the upper source line DSLb is removed.

As a result, a gap layer GPs is formed between the lower source line DSLa and the upper source line DSLb. A part of the memory layer ME of the outer peripheral portion of the pillar PL is exposed to inside of the gap layer GPs. Here, since the side wall of the slit ST is protected with the insulating layer 54s, the insulating layer NL in the stacked bodies LMsa and LMsb is also prevented from removal.

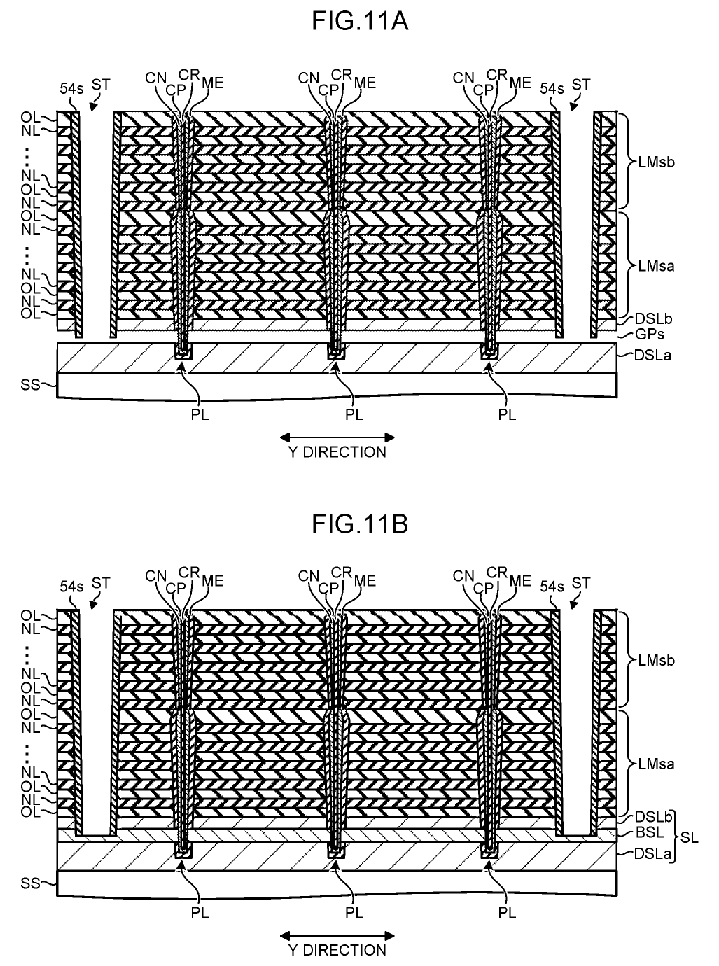

As illustrated in FIG. 11A, by appropriately flowing a chemical into the gap layer GPs via the slit ST, the block insulating layer BK, the charge storage layer CT, and the tunnel insulating layer TN (refer to FIGS. 2B and 2C) of the memory layer ME exposed to inside of the gap layer GPs are sequentially removed. As a result, the memory layer ME is removed from a part of the side wall of the pillar PL, and a part of the channel layer CN disposed inside is exposed to inside the gap layer GPs.

As illustrated in FIG. 11B, for example, raw material gas such as amorphous silicon is injected from the slit ST of which the side wall is protected with the insulating layer 54s, and the gap layer GPs is filled with the amorphous silicon or the like. By heating the supporting substrate SS, the amorphous silicon filled in the gap layer GPs is polycrystallized to form the intermediate source line BSL including polysilicon or the like.

As a result, a part of the channel layer CN of the pillar PL is connected to the source line SL on the side surface via the intermediate source line BSL.

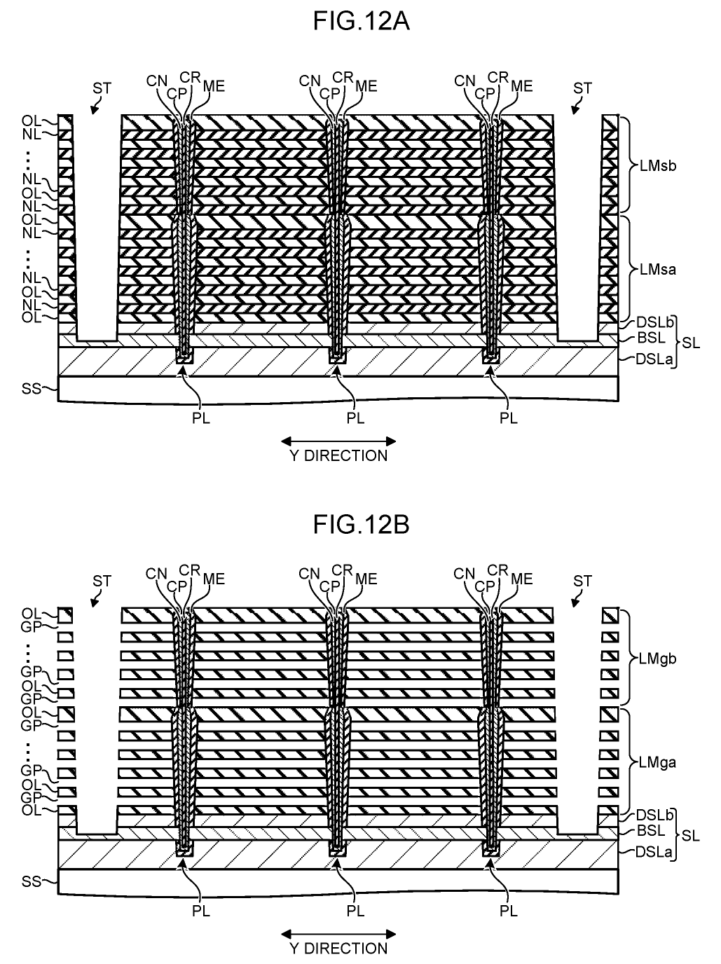

As illustrated in FIG. 12A, the insulating layer 54s of the slit ST side wall is removed.

As illustrated in FIG. 12B, by flowing a liquid such as hot phosphoric acid for removing the insulating layer NL into the stacked bodies LMsa and LMsb via the slit ST from which the insulating layer 54s is removed, the insulating layers NL of the stacked bodies LMsa and LMsb are removed. As a result, stacked bodies LMga and LMgb including a plurality of gap layers GP from which the insulating layer NL between the insulating layers OL is removed are formed.

The stacked bodies LMga and LMgb including the plurality of gap layers GP are weak structures. The plurality of pillars PL support the weak stacked bodies LMga and LMgb. As a result, bending of the remaining insulating layer OL in the stacked bodies LMga and LMgb or distortion and collapse of the stacked bodies LMga and LMgb is prevented.

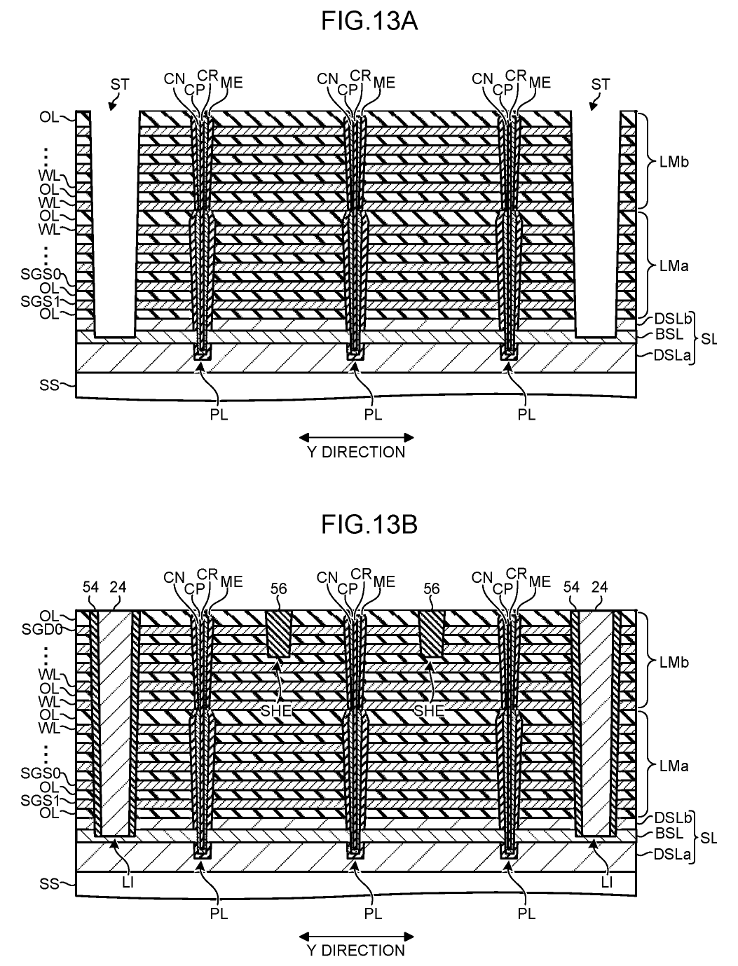

As illustrated in FIG. 13A, conductive raw material gas such as tungsten or molybdenum is injected into the stacked bodies LMga and LMgb via the slit ST, and the gap layers GP of the stacked bodies LMga and LMgb are filled with the conductive material to form the plurality of word lines WL and the like. As a result, the stacked body LM including the stacked bodies LMa and LMb in which the plurality of word lines WL and the like and the plurality of insulating layers OL are alternately stacked one by one is formed.

As described above, the treatment of forming the intermediate source line BSL from the intermediate sacrificial layer SCN and the treatment of forming the word line WL from the insulating layer NL will also be referred to as a replacement treatment.

As illustrated in FIG. 13B, the conductive layer 24 is filled in the slit ST via the insulating layer 54 to form the plate-like contact LI. By forming a groove penetrating one or a plurality of conductive layers including an uppermost conductive layer of the stacked body LMb and filling the insulating layers 56 in the groove, the conductive layers form the separation layers SHE divided to be a pattern of the selection gate line SGD.

Next, although not illustrated in the drawing, the plurality of contacts CC reaching each of the word lines WL and the selection gate lines SGD and SGS from the upper side of the staircase region SR are formed, each of the word lines WL and the selection gate lines SGD and SGS forming each step of the staircase structure of the staircase region SR.

After forming the insulating layer 52 covering the stacked body LM, the plug CH penetrating the insulating layer OL and the insulating layer 52 of the uppermost layer of the stacked body LM and connected to the cap layer CP of the upper end portion of the pillar PL is formed. The insulating layer 53 covering the insulating layer 52 is formed, and the bit line BL connected to each of the plugs CH is formed in the insulating layer 53.

For example, by using a dual damascene method or the like, the plug CH, the bit line BL, and the like may be collectively formed.

The peripheral circuit CBA is formed on the semiconductor substrate SB different from the supporting substrate SS in which the stacked body LM is formed, and is covered with the insulating layer 40. In the insulating layer 40, a contact, a via, a wiring, and the like for drawing the peripheral circuit CBA to the surface of the insulating layer 40 are formed, and are connected to an electrode pad or the like formed on the upper surface of the insulating layer 40.

Next, the supporting substrate SS and the semiconductor substrate SB are bonded by the insulating layers 50 and 40 provided in each substrate so that the electrode pads in the insulating layers 50 and 40 are connected. Next, the supporting substrate SS is removed so that the source line SL is exposed, and the electrode film EL is connected via the insulating layer 60 in which the plugs PG are formed.

Accordingly, the semiconductor device 1 according to the embodiment is manufactured.

### Summary

In the semiconductor device such as a three-dimensional nonvolatile memory, a technique of monocrystallizing a channel layer of a pillar is disclosed. As a result, carrier mobility in the channel layer can be improved and a trap by a grain boundary is not formed, and thus noise can be reduced. Crystallization of the amorphous channel layer or the like is performed, for example, by a metal-assisted annealing treatment in which a metal element such as nickel is introduced into the channel layer and used as a catalyst.

However, crystallization locally progresses at a plurality of positions in the channel layer from the metal element as an origin, the metal element being randomly diffused in the channel layer and silicided, and thus many grain boundaries are formed in the channel layer. As a result, grain size and grain boundary density of the channel layer vary for each word line or for each memory cell, and variation may occur in memory cell characteristics such as a cell current, a threshold voltage, and an operating speed during writing, reading, or the like.

In the semiconductor device 1 according to the embodiment, the pillar PL includes the semiconductor layer CS protruding from the side wall of the channel layer CN toward the insulating layer OLm at least at the height position of the insulating layer OLm positioned near the center of the stacked body LM in the stacking direction. As a result, an origin position of crystallization and a grain boundary position in the channel layer CN can be controlled, and crystallinity of the channel layer CN can be improved. As a result, variation in the grain size and the grain boundary density of the channel layer CN for each word line WL or each memory cell MC can be reduced, and variation in memory cell characteristics can be reduced.

In the semiconductor device 1 according to the embodiment, the insulating layer OLm includes the insulating layer OLb inserted at the height position of the semiconductor layer CS in the insulating layer OLm and having lower etching resistance than the insulating layer OLa. As a result, the insulating layer OLb is retracted from the side wall of the memory hole MH to form the recess portion RS, and the semiconductor layer CS functioning as an origin of crystallization of the channel layer CN can be formed in the recess portion RS.

In the semiconductor device 1 according to the embodiment, the plurality of semiconductor layers CS each protrude from the side wall of the channel layer CN toward the plurality of insulating layers OLm at the height positions of the plurality of insulating layers OLm scattered in the stacking direction of the stacked body LM. Accordingly, the semiconductor layer CS functioning as an origin of crystallization of the channel layer CN is disposed at a plurality of positions in the stacked body LM so that the entire channel layer CN can be crystallized.

### Modification Example

In the above-described embodiment, one or more semiconductor layers CS that are polysilicon layers or the like are disposed in the stacked body LM as an origin of crystallization of the channel layer CN. However, an amorphous semiconductor layer such as an amorphous silicon layer can also function as an origin of crystallization.

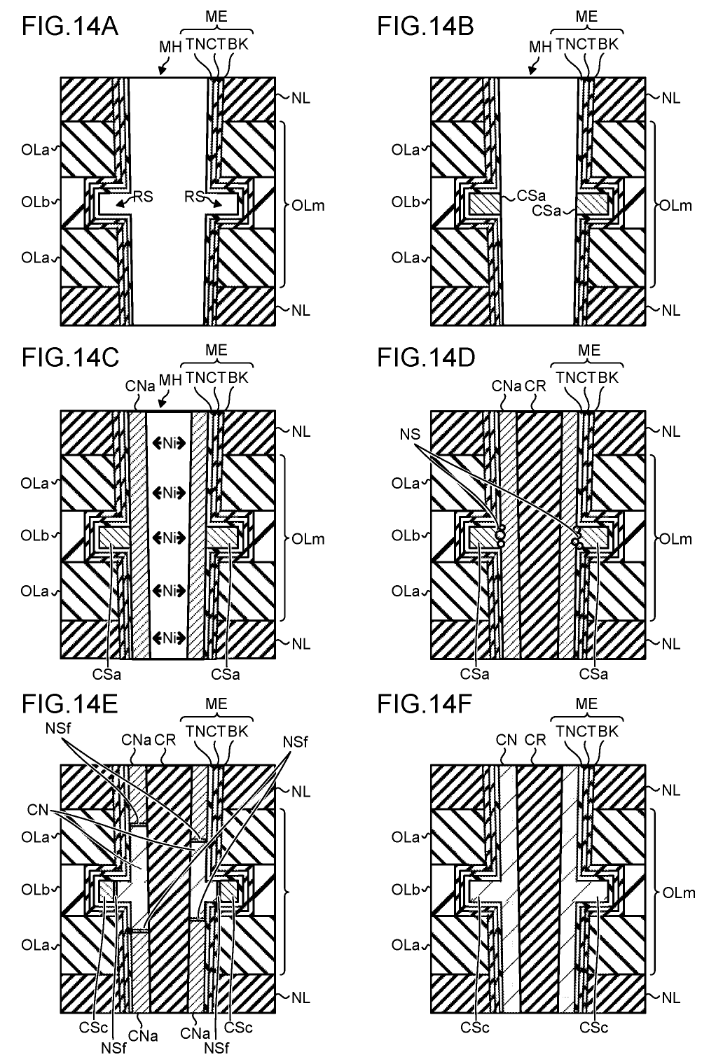

Hereinafter, a semiconductor device according to a modification example of the embodiment will be described using FIGS. 14A to 14F. The semiconductor device according to the modification example is different from the above-described embodiment in that a semiconductor layer CSa that is an amorphous silicon layer or the like is disposed at a predetermined position in the stacked body LM instead of the semiconductor layer CS such as a polysilicon layer.

FIGS. 14A to 14F are diagrams sequentially illustrating a part of a procedure of a method of manufacturing the semiconductor device according to the modification example of the embodiment. More specifically, FIGS. 14A to 14F are partially enlarged cross-sectional views at the height position of the insulating layer OLm of the pillar during manufacturing.

In FIGS. 14A to 14F, the same configurations as those of the above-described embodiment will be represented by the same reference numerals, and the description thereof may not be made.

As illustrated in FIG. 14A, in the semiconductor device according to the modification example, the memory hole MH penetrating the stacked bodies LMsa and LMsb including the insulating layer OLm is formed, the insulating layer OLb is retracted from the side wall of the memory hole MH to form the recess portion RS, and the memory layer ME covering the side wall of the memory hole MH including the recess portion RS is formed.

As illustrated in FIG. 14B, the amorphous semiconductor layer CSa such as an amorphous silicon layer is filled in the recess portion RS of the side wall of the memory hole MH. Here, an additive of at least any of nitrogen, boron, and carbon is added to the semiconductor layer CSa. A concentration of the additive in the semiconductor layer CS is, for example, 1 × 10²⁰ atm/cm³ or more and 3 × 10²¹ atm/cm³ or less, preferably 5 × 10²⁰ atm/cm³ or more and 2 × 10²¹ atm/cm³ or less, and more preferably 9 × 10²⁰ atm/cm³ or more and 1.5 × 10²¹ atm/cm³ or less.

As illustrated in FIG. 14C, the amorphous channel layer CNa covering the side wall of the memory hole MH including the semiconductor layer CSa is formed. Here, as in the above-described embodiment, an additive of at least any of nitrogen, boron, and carbon may be also added to the channel layer CNa. Note that, here, an additive concentration in the channel layer CNa is preferably less than an additive concentration in the semiconductor layer CS.

A metal layer covering the side wall of the channel layer CNa is formed, and a metal element such as nickel is introduced into the channel layer CNa.

Next, the core layer CR is filled in a void remaining in the memory hole MH, and an upper surface of the core layer CR is etched back to form the cap layer CP in a depression formed by etching back.

As illustrated in FIG. 14D, the entire supporting substrate SS is heated at a low temperature to perform the annealing treatment. Here, the semiconductor layer CSa as an amorphous silicon layer or the like includes an additive of at least one of nitrogen, boron, and carbon at a high concentration. As a result, the semiconductor layer CSa can function similarly to the semiconductor layer CS as a polysilicon layer or the like in the above-described embodiment.

That is, activation energy required for forming the silicide NS can be reduced at an interface between the semiconductor layer CSa and the channel layer CNa. The same additive as that in the channel layer CNa also promotes formation of the silicide NS.

As a result, aggregation of the silicide NS occurs at the interface between the semiconductor layer CSa and the channel layer CNa.

As illustrated in FIG. 14E, due to aggregation of the silicide NS, crystallization of the channel layer CNa progresses in the vertical direction of the stacked bodies LMsa and LMsb from the interface between the semiconductor layer CSa and the channel layer CNa as an origin. In the modification example, the semiconductor layer CSa is also an amorphous silicon layer or the like. Therefore, crystallization progresses from the memory hole MH side toward the periphery of the memory hole MH even in the semiconductor layer CSa.

Here, a part of the silicide NS as a catalyst for crystallization of the channel layer CNa and the semiconductor layer CSa is finely cut into the metal fragments NSf, and the metal fragments NSf are diffused in the channel layer CNa and the semiconductor layer CSa. The channel layer CNa of a part to which the metal fragment NSf entered changes into the above-described channel layer CN such as a single crystal silicon layer. The semiconductor layer CSa of a part to which the metal fragment NSf entered changes into a semiconductor layer CSc such as a single crystal silicon layer.

As such, in the modification example, crystallization is performed in parallel in the channel layer CNa and the semiconductor layer CSa. Therefore, the crystallized channel layer CN and the crystallized semiconductor layer CSc have the same crystal orientation.

Accordingly, also in the semiconductor device according to the modification example, the channel layer CN as a single crystal semiconductor layer or the like is formed.

In the method of manufacturing the semiconductor device according to the modification example, formation of the semiconductor layer CSc includes adding at least any of nitrogen, boron, and carbon and filling the amorphous semiconductor layer CSa in the recess portion RS of the side wall of the memory hole MH. Also by the above-described configuration, the semiconductor layer CSa can function as an origin of crystallization, and the same effects as those of the above-described embodiment are exhibited.

### Other Modification Examples

In the above-described embodiment and the modification example, the semiconductor device 1 includes the stacked body LM having a 2-tier structure in which the two stacked bodies LMa and LMb are vertically stacked. However, the configuration of the stacked body is not limited to 2 Tiers, and may be 1 Tier or may be 3 Tiers or more.

In the above-described embodiment and the modification example, the pillar PL is connected to the source line SL on the side surface of the channel layer CN, but the configuration is not limited thereto. For example, a memory layer of the bottom surface of the pillar may be removed so that the pillar is connected to the source line in the lower end portion of the channel layer.

In the above-described embodiment and the modification example, the peripheral circuit CBA is disposed above the stacked body LM. However, the peripheral circuit may be disposed below the stacked body or may be disposed on the same layer as the stacked body. When the peripheral circuit is disposed below the stacked body, the stacked body or the like can be directly formed above the semiconductor substrate on which the peripheral circuit is formed. When the peripheral circuit is disposed on the same layer as the stacked body, the stacked body can be formed at a different position from the peripheral circuit on the semiconductor substrate on which the peripheral circuit is formed.

In the above-described embodiment and the modification example, the semiconductor layer is crystallized in the metal-assisted annealing treatment and used as the channel layer CN of the memory cell MC in the semiconductor device 1 such as a three-dimensional nonvolatile memory. However, the semiconductor layer crystallized using the method of the above-described embodiment and the modification example can also be used as a switching circuit, a logic circuit, or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a stacked body in which a plurality of conductive layers and a plurality of insulating layers are alternately stacked one by one; and
a pillar extending in the stacked body in a stacking direction of the stacked body, wherein
the pillar includes
a first semiconductor layer extending in the stacked body in the stacking direction, and
a second semiconductor layer protruding from a side wall of the first semiconductor layer toward a first insulating layer at least at a height position of the first insulating layer positioned near a center of the stacked body in the stacking direction among the plurality of insulating layers.

2. The semiconductor device according to claim 1, wherein
the first semiconductor layer includes a single crystal semiconductor as a major component, and
the second semiconductor layer includes a single crystal semiconductor or a polycrystalline semiconductor as a major component.

3. The semiconductor device according to claim 2, wherein crystal orientations of the first semiconductor layer and the second semiconductor layer are different.

4. The semiconductor device according to claim 1, wherein, in the first and second semiconductor layers, the second semiconductor layer includes an additive of at least one selected from the group of nitrogen, boron, and carbon.

5. The semiconductor device according to claim 4, wherein the second semiconductor layer includes the additive at a concentration of 1 × 10²⁰ atm/cm³ or more and 3 × 10²¹ atm/cm³ or less.

6. The semiconductor device according to claim 1, wherein
the first semiconductor layer includes an additive of at least one selected from the group of nitrogen, boron, and carbon at a first concentration, and
the second semiconductor layer includes an additive of at least one selected from the group of nitrogen, boron, and carbon at a second concentration higher than the first concentration.

7. The semiconductor device according to claim 6, wherein the second concentration is 1 × 10²⁰ atm/cm³ or more and 3 × 10²¹ atm/cm³ or less.

8. The semiconductor device according to claim 1, wherein the first insulating layer includes a second insulating layer inserted at a height position of the second semiconductor layer in the first insulating layer and having lower etching resistance than the first insulating layer.

9. The semiconductor device according to claim 8, wherein
the first insulating layer is a silicon oxide layer, and
the second insulating layer is a silicon oxycarbide layer, a silicon-germanium layer, or a silicon oxide layer having a lower density than the first insulating layer.

10. The semiconductor device according to claim 1, wherein
the pillar includes a plurality of second semiconductor layers including the second semiconductor layer, and
the plurality of second semiconductor layers each protrude from a side wall of the first semiconductor layer toward first insulating layers at height positions of the first insulating layers, the first insulating layers including the first insulating layer and being scattered in the stacking direction of the stacked body among the plurality of insulating layers.

11. A method of manufacturing a semiconductor device, the method comprising:
forming a stacked body in which a plurality of sacrificial layers and a plurality of insulating layers are alternately stacked one by one;
forming a memory hole extending in the stacked body in a stacking direction of the stacked body; and
forming a pillar including a first semiconductor layer extending in the stacked body in the stacking direction in the memory hole, wherein
formation of the pillar includes
forming a recess portion that enters into a first insulating layer on a side wall of the memory hole at least at a height position of the first insulating layer positioned near a center of the stacked body in the stacking direction among the plurality of insulating layers,
filling a second semiconductor layer in the recess portion,
forming the first semiconductor layer covering the side wall of the memory hole and the second semiconductor layer, and
performing a metal-assisted annealing treatment on the first semiconductor layer.

12. The method of manufacturing a semiconductor device according to claim 11, wherein formation of the first semiconductor layer includes crystallizing the amorphous first semiconductor layer covering the side wall of the memory hole and the second semiconductor layer by the annealing treatment.

13. The method of manufacturing a semiconductor device according to claim 12, wherein formation of the second semiconductor layer includes filling the polycrystalline second semiconductor layer in the recess portion.

14. The method of manufacturing a semiconductor device according to claim 12, wherein formation of the second semiconductor layer includes filling the amorphous second semiconductor layer in the recess portion.

15. The method of manufacturing a semiconductor device according to claim 14, wherein formation of the second semiconductor layer includes crystallizing the second semiconductor layer filled in the recess portion by the annealing treatment.

16. The method of manufacturing a semiconductor device according to claim 14, wherein formation of the second semiconductor layer includes adding at least one selected from the group of nitrogen, boron, and carbon and filling the second semiconductor layer in the recess portion.

17. The method of manufacturing a semiconductor device according to claim 14, wherein
formation of the first semiconductor layer includes adding at least one selected from the group of nitrogen, boron, and carbon at a first concentration and forming the first semiconductor layer covering the side wall of the memory hole and the second semiconductor layer, and
formation of the second semiconductor layer includes adding at least one selected from the group of nitrogen, boron, and carbon at a second concentration higher than the first concentration and filling the second semiconductor layer in the recess portion.

18. The method of manufacturing a semiconductor device according to claim 11, wherein formation of the first insulating layer includes inserting a second insulating layer having lower etching resistance than the first insulating layer into the first insulating layer.

19. The method of manufacturing a semiconductor device according to claim 18, wherein the second insulating layer has a thickness of 80% or less of the first insulating layer.

20. The method of manufacturing a semiconductor device according to claim 18, wherein
the first insulating layer is a silicon oxide layer, and
the second insulating layer is a silicon oxycarbide layer, a silicon-germanium layer, or a silicon oxide layer having a lower density than the first insulating layer.
